(19) United States
(12) Patent Application Publication
(10) Pub. No.: US 2026/0206140 A1
(43) Pub. Date: Jul. 16, 2026

(54) SEMICONDUCTOR DEVICE

(71) Applicant: SUMITOMO ELECTRIC INDUSTRIES, LTD., Osaka-shi, Osaka (JP)

(72) Inventors: Tatsushi KANEDA, Osaka-shi, Osaka (JP); Hiroshi EGUSA, Osaka-shi, Osaka (JP); Hiromi KURASHIMA, Osaka-shi, Osaka (JP)

(73) Assignee: SUMITOMO ELECTRIC INDUSTRIES, LTD., Osaka-shi, Osaka (JP)

(21) Appl. No.: 18/867,847

(22) PCT Filed: Jul. 4, 2023
(86) PCT No.: PCT/JP2023/024808

§ 371 Date: Nov. 21, 2024

(30) Foreign Application Priority Data
Jul. 7, 2022 (JP) 2022-109874

(51) Int. Cl. H05K 1/181; H10W 90/00; H10W 90/10

(52) U.S. Cl. CPC H05K 1/181; H10W 90/10; H10W 90/754; H05K 2201/10272

(57) ABSTRACT

A semiconductor device according to an embodiment includes a circuit board including first and second conductive layers electrically connected to P-terminal and O-terminal portions, a first transistor including a first electrode electrically connected to the first conductive layer and a second electrode, a second transistor including a third electrode electrically connected to the second conductive layer and a fourth electrode, and a wiring portion including first and second plate-shaped conductive portions electrically connected to the N-terminal and O-terminal portions, wherein the second and forth electrodes are electrically connected to the second and first plate-shaped conductive portions, thickness directions of the first and second plate-shaped conductive portions are along a thickness direction of the circuit board, and the first and second plate-shaped conductive portions are arranged to be separated from each other in the thickness direction and in parallel to each other.

### TECHNICAL FIELD

The present disclosure relates to a semiconductor device.

The present application claims priority to Japanese Patent Application No. 2022-109874 filed on Jul. 7, 2022, and the entire contents of the Japanese patent application are incorporated herein by reference.

### BACKGROUND ART

A semiconductor device disclosed in Patent Literature 1 has been known as a technology of related art in this technical field. The semiconductor device described in Patent Literature 1 includes six MOS transistors. In this semiconductor device, three element pairs including two MOS transistors connected in series are connected in parallel. In the technology described in Patent Literature 1, in order to reduce a circuit inductance of the semiconductor device, a part of a wiring bus bar with respect to a P electrode and an N electrode is formed into a parallel plate shape.

### CITATION LIST

### Patent Literature

Patent Literature 1: Japanese Unexamined Patent Publication No. 2003-224243

### SUMMARY OF INVENTION

A semiconductor device according to the present disclosure includes a circuit board including a first conductive layer electrically connected to a P-terminal portion and a second conductive layer electrically connected to an O-terminal portion, a first transistor arranged on the first conductive layer, the first transistor including a first electrode electrically connected to the first conductive layer and a second electrode, a second transistor arranged on the second conductive layer, the second transistor including a third electrode electrically connected to the second conductive layer and a fourth electrode, and a wiring portion including a first plate-shaped conductive portion electrically connected to an N-terminal portion and a second plate-shaped conductive portion electrically connected to the O-terminal portion. The second electrode is electrically connected to the second plate-shaped conductive portion, the fourth electrode is electrically connected to the first plate-shaped conductive portion, thickness directions of the first plate-shaped conductive portion and the second plate-shaped conductive portion are along a thickness direction of the circuit board, and the first plate-shaped conductive portion and the second plate-shaped conductive portion are arranged to be separated from each other in the thickness direction and in parallel to each other.

### BRIEF DESCRIPTION OF DRAWINGS

FIG. 1 is a plan view illustrating a semiconductor device according to a first embodiment.

FIG. 2 is an exploded perspective view of the semiconductor device illustrated in FIG. 1.

FIG. 3 is a diagram schematically illustrating a part of a sectional structure taken along line III-III in FIG. 1.

FIG. 4 is a diagram for explaining an electric circuit realized by the semiconductor device.

FIG. 5 is a plan view illustrating a semiconductor device according to a second embodiment.

FIG. 6 is a diagram schematically illustrating a part of a sectional structure taken along line VI-VI in FIG. 5.

FIG. 7 is a plan view illustrating a semiconductor device according to a third embodiment.

FIG. 8 is a diagram for explaining a circuit board included in the semiconductor device illustrated in FIG. 7.

FIG. 9 is a diagram schematically illustrating a part of a sectional structure taken along line IX-IX in FIG. 7.

FIG. 10 is a plan view illustrating a semiconductor device according to a fourth embodiment.

FIG. 11 is a diagram schematically illustrating a part of a sectional structure taken along line XI-XI in FIG. 10.

FIG. 12 is a schematic view illustrating a modification of a wiring portion.

FIG. 13 is a schematic view illustrating another modification of the wiring portion.

FIG. 14 is a schematic view illustrating still another modification of the wiring portion.

FIG. 15 is a schematic view illustrating still another modification of the wiring portion.

### DESCRIPTION OF EMBODIMENTS

### Problem to be Solved by Present Disclosure

In the semiconductor device described in Patent Literature 1, the portion of the wiring bus bar with respect to the P electrode and the N electrode, which is formed into the parallel plate shape, extends in a thickness direction of the semiconductor device (a thickness direction of a substrate). In a case where the technology described in Patent Literature 1 is applied to a thin (small thickness) semiconductor device, since a degree of freedom in designing the semiconductor device decreases, it is difficult to implement the technology described in Patent Document 1 on the thin semiconductor device. Thus, it has been difficult to reduce an inductance in the thin semiconductor device.

An object of the present disclosure is to provide a semiconductor device capable of reducing an inductance with even a thin type.

### Effects of Present Disclosure

According to the present disclosure, it is possible to provide the semiconductor device capable of reducing the inductance with even the thin type.

### Description of Embodiments of Present Disclosure

First, contents of embodiments of the present disclosure are listed and described.

A semiconductor device according to the present disclosure is [1] a semiconductor device including a circuit board including a first conductive layer electrically connected to a P-terminal portion and a second conductive layer electrically connected to an O-terminal portion, a first transistor arranged on the first conductive layer, the first transistor including a first electrode electrically connected to the first conductive layer and a second electrode, a second transistor arranged on the second conductive layer, the second transistor including a third electrode electrically connected to the second conductive layer and a fourth electrode, and a wiring portion including a first plate-shaped conductive portion electrically connected to an N-terminal portion and a second plate-shaped conductive portion electrically connected to the O-terminal portion. The second electrode is electrically connected to the second plate-shaped conductive portion, the fourth electrode is electrically connected to the first plate-shaped conductive portion, thickness directions of the first plate-shaped conductive portion and the second plate-shaped conductive portion are along a thickness direction of the circuit board, and the first plate-shaped conductive portion and the second plate-shaped conductive portion are arranged to be separated from each other in the thickness direction and in parallel to each other.

The first transistor, the second transistor, the first conductive layer, the second conductive layer, the first plate-shaped conductive portion, and the second plate-shaped conductive portion included in the semiconductor device have the electrical connection relationship described above. Thus, the semiconductor device can operate as a power conversion circuit. In the semiconductor device, the first conductive layer electrically connected to the P-terminal portion is electrically connected to the first electrode of the first transistor, and the second electrode of the first transistor is electrically connected to the second plate-shaped conductive portion. The second plate-shaped conductive portion is electrically connected to the O-terminal portion, and the O-terminal portion is electrically connected to the second conductive layer. The second conductive layer is electrically connected to the third electrode of the second transistor, and the fourth electrode of the second transistor is electrically connected to the first plate-shaped conductive portion electrically connected to the N-terminal portion. In such a connection relationship, in a case where the semiconductor device is operated as the power conversion circuit, a direction of change (increase or decrease) of a current flowing through the first plate-shaped conductive portion is opposite to a direction of change of a current flowing through the second plate-shaped conductive portion. The first plate-shaped conductive portion and the second plate-shaped conductive portion are arranged in parallel to each other. Thus, magnetic fluxes generated by the changes in the currents flowing through the first plate-shaped conductive portion and the second plate-shaped conductive portion are mutually canceled, and as a result, the inductance is reduced. Since the thickness directions of the first plate-shaped conductive portion and the second plate-shaped conductive portion are along the thickness direction of the circuit board, the first plate-shaped conductive portion and the second plate-shaped conductive portion are arranged in the thickness direction of the circuit board. Thus, even in a semiconductor device (thin semiconductor device) having a short length in the thickness direction of the circuit board, the wiring portion for reducing the inductance can be implemented on the semiconductor device.

[2] In the above [1], the first plate-shaped conductive portion and the second plate-shaped conductive portion may be separated from the circuit board and may be parallel to the circuit board. In this case, the semiconductor device (thin semiconductor device) having the short length in the thickness direction of the circuit board can be easily realized.

[3] The semiconductor device according to the aspect described in the above [2] may further include a case configured to accommodate the first transistor and the second transistor arranged on the circuit board. The first plate-shaped conductive portion and the second plate-shaped conductive portion may be fixed to the case. In this case, the wiring portion can be arranged to be separated from the circuit board.

[4] The semiconductor device according to the aspect described in the above [3] may further include the P-terminal portion, the N-terminal portion, and the O-terminal portion. The P-terminal portion, the N-terminal portion, and the O-terminal portion may be fixed to the case, the first plate-shaped conductive portion may be directly connected to the N-terminal portion, the second plate-shaped conductive portion is directly connected to the O-terminal portion, the first conductive layer may be connected to the P-terminal portion by a wiring member, and the second conductive layer may be connected to the O-terminal portion by a wiring member.

In this case, the first plate-shaped conductive portion is directly connected to the N-terminal portion fixed to the case. Accordingly, the first plate-shaped conductive portion is fixed to the case. The second plate-shaped conductive portion is directly connected to the O-terminal portion fixed to the case. Accordingly, the second plate-shaped conductive portion is also fixed to the case. Since the first conductive layer is connected to the P-terminal portion by the wiring member, the first conductive layer is electrically connected to the P-terminal portion. Since the second conductive layer is connected to the O-terminal portion by the wiring member, the second conductive layer is electrically connected to the O-terminal portion.

[5] In the above [3] or the above [4], the wiring portion may include an insulating resin portion configured to insulate the first plate-shaped conductive portion and the second plate-shaped conductive portion, and the first plate-shaped conductive portion and the second plate-shaped conductive portion may be inserted into the insulating resin portion. In this case, the insulation between the first plate-shaped conductive portion and the second plate-shaped conductive portion can be reliably secured.

[6] In the above [3] or the above [4], the wiring portion may include an insulating paper configured to insulate the first plate-shaped conductive portion and the second plate-shaped conductive portion, and the insulating paper may be positioned between the first plate-shaped conductive portion and the second plate-shaped conductive portion. In this case, the insulating paper is arranged between the first plate-shaped conductive portion and the second plate-shaped conductive portion. Thus, uniformity of a distance between the first plate-shaped conductive portion and the second plate-shaped conductive portion is secured in extending directions of the first plate-shaped conductive portion and the second plate-shaped conductive portion. That is, parallel states of the first plate-shaped conductive portion and the second plate-shaped conductive portion can be reliably maintained in the extending directions of the first plate-shaped conductive portion and the second plate-shaped conductive portion. Further, the insulation between the first plate-shaped conductive portion and the second plate-shaped conductive portion can also be secured by the insulating paper.

[7] The semiconductor device according to any one of the aspects of the above [2] to the above [6] may further include a first heat dissipation member arranged between the first transistor and the first conductive layer, and a second heat dissipation member arranged between the second transistor and the second conductive layer. In this case, heat of the first transistor and the second transistor can be efficiently dissipated. Further, the first transistor and the second transistor can be arranged close to the wiring portion.

[8] In the above [1], in a case where one of the first plate-shaped conductive portion and the second plate-shaped conductive portion is referred to as an i-th plate-shaped conductive portion (i is 1 or 2), the i-th plate-shaped conductive portion may be arranged on the circuit board. In this case, one of the first plate-shaped conductive portion and the second plate-shaped conductive portion is arranged on the circuit board. Thus, it is easier to implement the wiring portion on the semiconductor device than in a case where both the first plate-shaped conductive portion and the second plate-shaped conductive portion are arranged to be separated from the circuit board.

[9] In the above [8], in a case where a plate-shaped conductive portion other than the i-th plate-shaped conductive portion, of the first plate-shaped conductive portion and the second plate-shaped conductive portion, is referred to as a k-th plate-shaped conductive portion (k is other than i of 1 and 2), the k-th plate-shaped conductive portion may be arranged on the i-th plate-shaped conductive portion with an insulating paper interposed therebetween. In this case, the insulation between the i-th plate-shaped conductive portion and the k-th plate-shaped conductive portion can be more reliably secured by the insulating paper.

[10] In the above [8], the wiring portion may include an insulating resin portion, and in a case where a plate-shaped conductive portion other than the i-th plate-shaped conductive portion, of the first plate-shaped conductive portion and the second plate-shaped conductive portion, is referred to as a k-th plate-shaped conductive portion (k is other than i of 1 and 2), the k-th plate-shaped conductive portion may be inserted into the insulating resin portion, a part of the k-th plate-shaped conductive portion may be exposed from the insulating resin portion, and the k-th plate-shaped conductive portion may be arranged on the i-th plate-shaped conductive portion in a state where the insulating resin portion is sandwiched between the k-th plate-shaped conductive portion and the i-th plate-shaped conductive portion. In this case, the insulating resin portion can more reliably secure the insulation between the i-th plate-shaped conductive portion and the k-th plate-shaped conductive portion.

[11] In any one of the above [8] to the above [10], the i-th plate-shaped conductive portion may be the second plate-shaped conductive portion, and the second plate-shaped conductive portion is a part of the second conductive layer. In this case, a part of the second conductive layer is used as the second plate-shaped conductive portion. Thus, the configuration of the semiconductor device can be simplified, and the manufacturing cost can be reduced.

[12] In the above [8], the i-th plate-shaped conductive portion may be the second plate-shaped conductive portion, the second plate-shaped conductive portion may be a part of the second conductive layer, the wiring portion includes an insulating resin portion, the first plate-shaped conductive portion and the second plate-shaped conductive portion may be inserted into the insulating resin portion, a part of each of the first plate-shaped conductive portion and the second plate-shaped conductive portion may be exposed from the insulating resin portion, and the second plate-shaped conductive portion may be fixed to the second conductive layer in a state where a portion of the second plate-shaped conductive portion exposed from the insulating resin portion is electrically connected to the second conductive layer.

In this case, a part of the second conductive layer is used as the second plate-shaped conductive portion. Thus, the configuration of the semiconductor device can be simplified, and the manufacturing cost can be reduced. Further, the insulating resin portion can more reliably secure the insulation between the first plate-shaped conductive portion and the second plate-shaped conductive portion.

[13] The semiconductor device according to the above [11] or the above [12] may further include the P-terminal portion, the N-terminal portion, and the O-terminal portion. The first conductive layer may be connected to the P-terminal portion by a wiring member, the second conductive layer may be connected to the O-terminal portion by a wiring member, and the first plate-shaped conductive portion may be connected to the N-terminal portion by a wiring member.

In this case, the first conductive layer is electrically connected to the P-terminal portion, and the first plate-shaped conductive portion is electrically connected to the N-terminal portion. Further, since the second conductive layer is electrically connected to the O-terminal portion, a part of the second conductive layer or the second plate-shaped conductive portion electrically connected to the second conductive layer is also electrically connected to the O-terminal portion. With such a wiring structure, the semiconductor device can be operated as the power conversion circuit.

[14] In the above [1], the circuit board may include a third conductive layer arranged between the first conductive layer and the second conductive layer, and the first plate-shaped conductive portion may be the third conductive layer. In this case, since the third conductive layer included in the circuit board is the first plate-shaped conductive portion, it is easier to implement the wiring portion on the semiconductor device than in a case where both the first plate-shaped conductive portion and the second plate-shaped conductive portion are arranged to be separated from the circuit board.

[15] The semiconductor device according to the aspect described in the above [14] may further include the P-terminal portion, the N-terminal portion, and the O-terminal portion. The first conductive layer may be connected to the P-terminal portion by a wiring member, the second conductive layer may be connected to the O-terminal portion by a wiring member, the third conductive layer may be connected to the N-terminal portion by a wiring member, and the second plate-shaped conductive portion may be connected to the O-terminal portion directly or by a wiring member.

In this case, the first conductive layer and the second conductive layer are electrically connected to the P-terminal portion and the O-terminal portion. Since the third conductive layer is the first plate-shaped conductive portion, the first plate-shaped conductive portion is electrically connected to the N-terminal portion. Further, the second plate-shaped conductive portion is electrically connected to the O-terminal portion. With such a wiring structure, the semiconductor device can be operated as the power conversion circuit.

### Details of Embodiment of Present Disclosure

A specific example of an embodiment of the present disclosure will now be described with reference to the drawings. It should be noted that the present invention is not limited to these examples, is described by the claims, and is intended to include meanings equivalent to the claims and all changes within the scope of the claims. In the description of the drawings, the same elements are denoted by the same reference signs, and a repeated description is omitted.

### First Embodiment

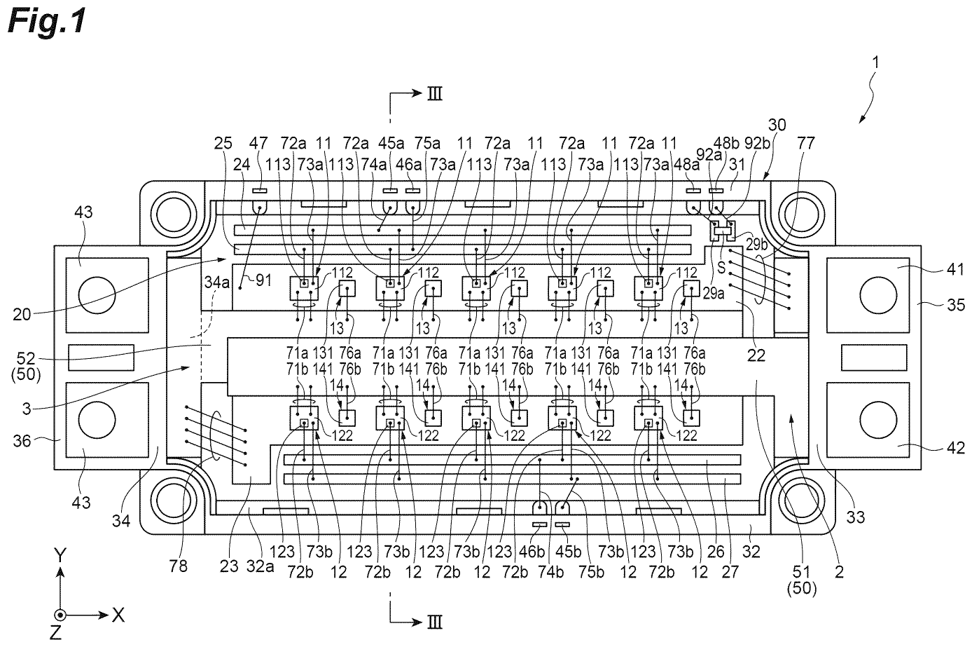

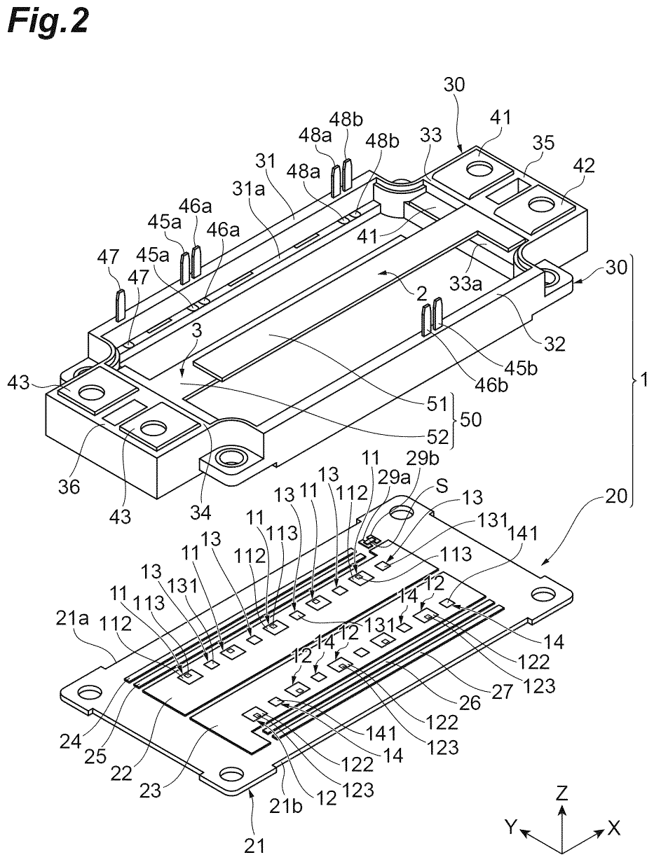

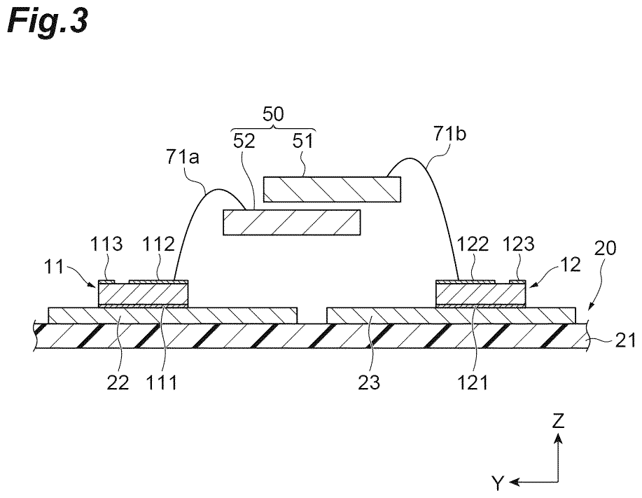

FIG. 1 is a plan view of a semiconductor device according to a first embodiment. FIG. 2 is an exploded perspective view of the semiconductor device illustrated in FIG. 1. FIG. 3 is a diagram schematically illustrating a part of a sectional structure taken along line II-III of FIG. 1.

As illustrated in FIGS. 1 and 2, a semiconductor device 1 includes a plurality of first transistors 11, a plurality of second transistors 12, a circuit board 20, and a wiring portion 50. An example of the semiconductor device 1 is a semiconductor module that functions as a power conversion device. An example of the power conversion device is an inverter.

The plurality of first transistors 11 and the plurality of second transistors 12 are mounted on the circuit board 20. In the first embodiment, the first transistor 11 and the second transistor 12 are metal-oxide-semiconductor field-effect transistors (MOSFET). The semiconductor device 1 may include a case 30 that accommodates the plurality of first transistors 11, the plurality of second transistors 12, and the wiring portion 50. In the first embodiment, unless otherwise specified, a case where the semiconductor device 1 includes a frame-shaped case 30 will be described.

Hereinafter, as illustrated in FIGS. 1 and 2, a thickness direction of the circuit board 20 may be referred to as a Z direction, and two directions orthogonal to the Z direction may be referred to as an X direction and a Y direction. For the sake of convenience in description, in the case 30, a side on which the circuit board 20 is arranged may be referred to as a “lower” side, and a side opposite to the circuit board 20 may be referred to as an “upper” side. In the first embodiment, the X direction is along an extending direction of a side wall portion 31 or a side wall portion 32 of the case 30, and is a direction from a terminal block 36 of the case 30 toward a terminal block 35.

The circuit board 20 is attached to the case 30. The circuit board 20 closes a lower opening of the frame-shaped case 30. A shape of the circuit board 20 viewed from the thickness direction of the circuit board 20 is rectangular. The circuit board 20 includes an insulating substrate 21.

The insulating substrate 21 is, for example, a ceramic substrate. Examples of a material of the insulating substrate 21 include aluminum nitride (AlN), silicon nitride (SiN), and aluminum oxide (Al₂O₃). A conductive layer (first conductive layer) 22, a conductive layer (second conductive layer) 23, a conductive layer 24, a conductive layer 25, a conductive layer 26, and a conductive layer 27 are provided on a front surface of the insulating substrate 21. Each of the conductive layers 22, 23, 24, 25, 26, and 27 functions as a wiring region. In one example, a heat dissipation layer or a heat dissipation plate is provided on a back surface of the insulating substrate 21.

The conductive layers 22, 23, 24, 25, 26, and 27 are arranged to be separated from each other. An example of a material of the conductive layers 22, 23, 24, 25, 26, and 27 is copper. The conductive layer 22 and the conductive layer 23 are adjacent to each other in a Y direction. The conductive layer 24 and the conductive layer 25 are arranged between an edge portion 21a of the insulating substrate 21 and the conductive layer 22. The conductive layer 26 and the conductive layer 27 are arranged between an edge portion 21b of the insulating substrate 21 and the conductive layer 23. The edge portion 21b is positioned opposite to the edge portion 21a as viewed from the conductive layer 23 (or the conductive layer 22).

The plurality of first transistors 11 are mounted on the conductive layer 22. In one embodiment, the plurality of first transistors 11 are arranged along an X direction. The first transistor 11 is a vertical transistor. The first transistor 11 includes a drain electrode (first electrode) 111, a source electrode (second electrode) 112, and a gate electrode (control electrode) 113 (see FIG. 3). The first transistor 11 may be a horizontal transistor.

The drain electrode 111 is bonded to the conductive layer 22 by, for example, a bonding material having conductivity. Thus, the drain electrode 111 is electrically connected to the conductive layer 22. Examples of the bonding material include solder and a sintered material. The source electrode 112 and the gate electrode 113 are positioned opposite to the drain electrode 111 in the Z direction. The source electrode 112 and the gate electrode 113 are insulated. Examples of a material of the first transistor 11 include a wide bandgap semiconductor and Si. Examples of the wide bandgap semiconductor include silicon carbide (SiC) and gallium nitride (GaN).

The plurality of second transistors 12 are mounted on the conductive layer 23. In one embodiment, the plurality of second transistors 12 are arranged along the X direction. The second transistor 12 is a vertical transistor. The second transistor 12 includes a drain electrode (third electrode) 121, a source electrode (fourth electrode) 122, and a gate electrode (control electrode) 123 (see FIG. 3). The second transistor 12 may be a lateral transistor.

The drain electrode 121 is bonded to the conductive layer 23 by, for example, a bonding material having conductivity (for example, solder, sintered material, or the like). Thus, the drain electrode 121 is electrically connected to the conductive layer 23. The source electrode 122 and the gate electrode 123 are positioned opposite to the drain electrode 121 in the Z direction. The source electrode 122 and the gate electrode 123 are insulated. An example of a material of the second transistor 12 is the same as the example of the material of the first transistor 11.

As illustrated in FIGS. 1 and 2, the semiconductor device 1 may include a plurality of first diodes 13 and a plurality of second diodes 14.

The plurality of first diodes 13 are mounted on the conductive layer 22. In one embodiment, the plurality of first diodes 13 are arranged along the X direction. The first diode 13 functions as a freewheeling diode. An example of the first diode 13 is a Schottky barrier diode. An example of a material of the first diode 13 is the same as the example of the material of the first transistor 11. A cathode electrode (not illustrated) of the first diode 13 is bonded to the conductive layer 22 by, for example, a bonding material (for example, solder, sintered material, or the like) having conductivity. Thus, the cathode electrode of the first diode 13 is electrically connected to the conductive layer 22. Accordingly, the cathode electrode of the first diode 13 is electrically connected to the drain electrode 111 by the conductive layer 22.

The plurality of second diodes 14 are mounted on the conductive layer 23. In one embodiment, the plurality of second diodes 14 are arranged along the X direction. The second diode 14 functions as a freewheeling diode. An example of the second diode 14 is a Schottky barrier diode. An example of a material of the second diode 14 is the same as the example of the material of the first transistor 11. A cathode electrode (not illustrated) of the second diode 14 is bonded to the conductive layer 23 by, for example, a bonding material (for example, solder, sintered material, or the like) having conductivity. Thus, the cathode electrode of the second diode 14 is electrically connected to the conductive layer 23. Accordingly, the cathode electrode of the second diode 14 is electrically connected to the drain electrode 121 of the second transistor 12 by the conductive layer 23.

In one embodiment, a thermistor S is mounted on the circuit board 20. In an aspect in which the thermistor S is mounted on the circuit board 20, the circuit board 20 has a conductive layer 29a and a conductive layer 29b. The thermistor S is electrically connected to the conductive layer 29a and the conductive layer 29b to connect the conductive layer 29a and the conductive layer 29b.

The case 30 is formed in a frame shape in plan view (as viewed from the Z direction). The case 30 has an insulating property. An example of a material of the case 30 is resin. The case 30 includes the side wall portion 31, the side wall portion 32, the side wall portion 33, the side wall portion 34, the terminal block 35, and the terminal block 36.

The side wall portion 31 and the side wall portion 32 face each other in the Y direction. A stepped portion 31a (see FIG. 2) is formed on an inner surface of the side wall portion 31. A stepped portion 32a (see FIG. 1) is formed on an inner surface of the side wall portion 32. The inner surface of the side wall portion 31 is a surface of the side wall portion 31 facing the side wall portion 32, and the inner surface of the side wall portion 32 is a surface of the side wall portion 32 facing the side wall portion 31.

The side wall portion 33 and the side wall portion 34 face each other in the X direction. The side wall portion 33 and the side wall portion 34 connect both end portions of the side wall portion 31 and the side wall portion 32. A stepped portion 33a (see FIG. 2) is formed on an inner surface of the side wall portion 33. A stepped portion 34a (see FIG. 1) is formed on an inner surface of the side wall portion 34. The inner surface of the side wall portion 33 is a surface of the side wall portion 33 facing the side wall portion 34, and the inner surface of the side wall portion 34 is a surface of the side wall portion 34 facing the side wall portion 33.

The terminal block 35 protrudes in a direction opposite to the side wall portion 34 as viewed from the side wall portion 33. The terminal block 36 protrudes in a direction opposite to the side wall portion 33 as viewed from the side wall portion 34.

A P-terminal portion 41, an N-terminal portion 42, an O-terminal portion 43, a first gate terminal portion 46a, and a second gate terminal portion 46b are attached to the case 30. A first sense source terminal portion 45a and a second sense source terminal portion 45b may be attached to the case 30. A sense drain terminal portion 47 may be attached to the case 30. A first thermistor terminal portion 48a and a second thermistor terminal portion 48b may be attached to the case 30. Hereinafter, unless otherwise specified, an aspect in which the first sense source terminal portion 45a and the second sense source terminal portion 45b, the sense drain terminal portion 47, and the first thermistor terminal portion 48a and the second thermistor terminal portion 48b are attached will be described.

The P-terminal portion 41 functions as a positive power supply terminal or a high-voltage power supply terminal. An example of the P-terminal portion 41 is a metal plate. An example of the P-terminal portion 41 is a bus bar. The P-terminal portion 41 is attached to the terminal block 35. In the first embodiment, a first end portion of the P-terminal portion 41 is exposed on an upper surface of the terminal block 35. A second end portion of the P-terminal portion 41 is exposed from the inner surface of the side wall portion 33. The second end portion of the P-terminal portion 41 is an end portion opposite to the first end portion of the P-terminal portion 41. The second end portion of the P-terminal portion 41 is arranged in the stepped portion 33a. A part of the P-terminal portion 41 is embedded in the terminal block 35. Specifically, a portion of the P-terminal portion 41 between the first terminal portion and the second terminal portion is embedded in the terminal block 35.

The N-terminal portion 42 functions as a negative power supply terminal or a low-voltage power supply terminal. The N-terminal portion 42 is a metal plate. An example of the N-terminal portion 42 is a bus bar. The N-terminal portion 42 is attached to the terminal block 35. In the first embodiment, a first end portion of the N-terminal portion 42 is exposed on the upper surface of the terminal block 35. A second end portion of the N-terminal portion 42 is exposed from the inner surface of the side wall portion 33. The second end portion of the N-terminal portion 42 is an end portion opposite to the first end portion of the N-terminal portion 42. A part of the N-terminal portion 42 is embedded in the terminal block 35. Specifically, a portion between the first terminal portion and the second terminal portion of the N-terminal portion 42 is embedded in the terminal block 35.

The O-terminal portion 43 functions as an output terminal. The O-terminal portion 43 is a metal plate. An example of the O-terminal portion 43 is a bus bar. The O-terminal portion 43 is attached to the terminal block 36. In the first embodiment, a first end portion of the O-terminal portion 43 is exposed on an upper surface of the terminal block 36. In the first embodiment, the first end portion of the O-terminal portion 43 branches into two. The second end portion (an end portion opposite to the first end portion) of the O-terminal portion 43 is exposed from the inner surface of the side wall portion 34. The second end portion of the O-terminal portion 43 is an end portion opposite to the first end portion of the O-terminal portion 43. The second end portion of the O-terminal portion 43 is arranged on the stepped portion 34a. A part of the O-terminal portion 43 is embedded in the terminal block 36. Specifically, a portion between the first end portion and the second end portion of the O-terminal portion 43 is embedded in the terminal block 36.

The first gate terminal portion 46a functions as a control terminal for the first transistor 11. The first sense source terminal portion 45a functions as a terminal for detecting a potential of the source electrode 112. The first gate terminal portion 46a and the first sense source terminal portion 45a are metal plates. Examples of the first gate terminal portion 46a and the first sense source terminal portion 45a are bus bars.

The first gate terminal portion 46a and the first sense source terminal portion 45a are attached to the side wall portion 31. In the first embodiment, a first end portion of the first gate terminal portion 46a is exposed from an upper surface of the side wall portion 31. A second end portion of the first gate terminal portion 46a is exposed from the inner surface of the side wall portion 31. The second end portion of the first gate terminal portion 46a is an end portion opposite to the first end portion of the first gate terminal portion 46a. The second end portion of the first gate terminal portion 46a is arranged on the stepped portion 31a. A part of the first gate terminal portion 46a is embedded in the side wall portion 31. Specifically, a portion between the first end portion and the second end portion of the first gate terminal portion 46a is embedded in the side wall portion 31. The first end portion of the first sense source terminal portion 45a is exposed from the upper surface of the side wall portion 31. The second end portion of the first sense source terminal portion 45a is exposed from the inner surface of the side wall portion 31. The second end portion of the first sense source terminal portion 45a is an end portion opposite to the first end portion of the first sense source terminal portion 45a. The second end portion of the first sense source terminal portion 45a is arranged on the stepped portion 31a. A part of the first sense source terminal portion 45a is embedded in the side wall portion 31. Specifically, a portion between the first end portion and the second end portion of the first sense source terminal portion 45a is embedded in the side wall portion 31.

The sense drain terminal portion 47 functions as a terminal used in a case where a potential of the drain electrode 111 (or a potential of the conductive layer 22) is detected. The sense drain terminal portion 47 is attached to the side wall portion 31 in the same manner as in the case of the first gate terminal portion 46a or the first sense source terminal portion 45a.

In the aspect in which the thermistor S is mounted on the circuit board 20, the first thermistor terminal portion 48a and the second thermistor terminal portion 48b function as terminals for externally connecting the thermistor S. The first thermistor terminal portion 48a and the second thermistor terminal portion 48b are attached to the side wall portion 31 in the same manner as in the case of the first gate terminal portion 46a or the first sense source terminal portion 45a.

The second gate terminal portion 46b functions as a control terminal for the second transistor 12. The second sense source terminal portion 45b is a terminal for detecting a potential of the source electrode 122. Examples of the second gate terminal portion 46b and the second sense source terminal portion 45b are metal plates. Examples of the second gate terminal portion 46b and the second sense source terminal portion 45b are bus bars.

The second gate terminal portion 46b and the second sense source terminal portion 45b are attached to the side wall portion 32. In the first embodiment, a part of the second gate terminal portion 46b and a part of the second sense source terminal portion 45b are embedded in the side wall portion 32. One end portion of each of the second gate terminal portion 46b and the second sense source terminal portion 45b is exposed from an upper surface of the side wall portion 32. The other end portion of each of the second gate terminal portion 46b and the second sense source terminal portion 45b is exposed from the inner surface of the side wall portion 32. The other end portion of each of the second gate terminal portion 46b and the second sense source terminal portion 45b is arranged on the stepped portion 32a.

The wiring portion 50 includes a plate-shaped conductive portion (first plate-shaped conductive portion) 51 and a plate-shaped conductive portion (second plate-shaped conductive portion) 52. Examples of the conductive portion 51 and the conductive portion 52 are metal plates. The conductive portion 51 and the conductive portion 52 extend in the X direction. The conductive portion 51 and the conductive portion 52 are arranged such that thicknesses face the Z direction. The conductive portion 51 and the conductive portion 52 are parallel to each other. The conductive portion 51 and the conductive portion 52 are separated from each other in the Z direction. The conductive portion 51 and the conductive portion 52 at least partially overlap as viewed from the Z direction. In one embodiment, the conductive portion 51 and the conductive portion 52 are positioned on opposing edge portions of the conductive layer 22 and the conductive layer 23, or on a gap between the conductive layer 22 and the conductive layer 23.

The conductive portion 51 is electrically connected to the N-terminal portion 42. For example, an end portion of the conductive portion 51 close to the side wall portion 33 is integrally connected to a portion of the second end portion of the N-terminal portion 42 exposed in the case 30. In the first embodiment, unless otherwise specified, the N-terminal portion 42 and the conductive portion 51 are one metal plate 2, for example, a bus bar. That is, in the metal plate 2, a region close to the terminal block 35 functions as the N-terminal portion 42, and a region above the circuit board 20 functions as the conductive portion 51.

The conductive portion 52 is electrically connected to the O-terminal portion 43. For example, an end portion of the conductive portion 52 close to the side wall portion 34 is integrally connected to a portion of the second end portion of the O-terminal portion 43 exposed in the case 30. In the first embodiment, the O-terminal portion 43 and the conductive portion 52 are one metal plate 3, for example, a bus bar. That is, in the metal plate 3, a region close to the terminal block 36 functions as the O-terminal portion 43, and a region above the circuit board 20 functions as the conductive portion 52.

For the sake of convenience in description, in the metal plate 2, a region functioning as the N-terminal portion 42 and a region functioning as the conductive portion 51 may be referred to as an N-terminal region and a first conductive region, respectively. Similarly, in the metal plate 3, a region functioning as the O-terminal portion 43 and a region functioning as the conductive portion 52 may be referred to as an O-terminal region and a second conductive region, respectively.

As described above, the conductive portion 51 and the conductive portion 52 are separated from each other in the Z direction. Accordingly, as described above, in an aspect in which the metal plate 2 and the metal plate 3 are used, a position at which the metal plate 2 is exposed from the inner surface of the side wall portion 33 and a position at which the metal plate 3 is exposed from the inner surface of the side wall portion 34 may be adjusted. Alternatively, in the metal plate 2, the metal plate 2 may be bent such that the conductive portion 51 and the conductive portion 52 are separated from each other in the Z direction at a boundary region between the conductive portion 51 and the N-terminal portion 42. Conversely, in the metal plate 3, the metal plate 3 may be bent such that the conductive portion 51 and the conductive portion 52 are separated from each other in the Z direction at a boundary region between the O-terminal portion 43 and the conductive portion 52.

Next, a wiring structure in the semiconductor device will be described with reference to FIGS. 1 and 3.

The drain electrode 111 of each first transistor 11 and the cathode electrode of each first diode 13 are electrically connected to the conductive layer 22 as described above. The conductive layer 22 is connected, by a wire 77, to a portion of the second end portion of the P-terminal portion 41 exposed in the case 30. Thus, the drain electrode 111 of each first transistor 11 and the cathode electrode of each first diode 13 are electrically connected to the P-terminal portion 41.

The source electrode 112 of each first transistor 11 is connected to the conductive portion 52 by a wire (wiring member) 71a. An anode electrode 131 of each first diode 13 is connected to the conductive portion 52 by a wire 76a. In the first embodiment, the conductive portion 52 is a part of the metal plate 3. A part of the metal plate 3 also functions as the O-terminal portion 43. Accordingly, each source electrode 112 and each anode electrode are electrically connected to the O-terminal portion 43.

The source electrode 112 is further connected to the conductive layer 24 by a wire 73a. The conductive layer 24 is connected to the first sense source terminal portion 45a by a wire 74a. As a result, the source electrode 112 and the first sense source terminal portion 45a are electrically connected.

The gate electrode 113 of each first transistor 11 is connected to the conductive layer 25 by a wire 72a. The conductive layer 25 is connected to the first gate terminal portion 46a by a wire 75a. Thus, each gate electrode 113 is electrically connected to the first gate terminal portion 46a.

The drain electrode 121 of each second transistor 12 and the cathode electrode of each second diode 14 are electrically connected to the conductive layer 23 as described above. The conductive layer 23 is connected, by a wire 78, to the portion of the second end portion of the O-terminal portion 43 exposed in the case 30. As a result, the drain electrode 121 of each second transistor 12 and the cathode electrode of each second diode 14 are electrically connected.

The source electrode 122 of each second transistor 12 is connected to the conductive portion 51 by a wire (wiring member) 71b. The anode electrode 131 of each second diode 14 is connected to the conductive portion 51 by a wire 76b. In the first embodiment, the conductive portion 51 is a part of the metal plate 2. A part of the metal plate 2 functions as the N-terminal portion 42. Accordingly, each source electrode 122 and each anode electrode 141 are electrically connected to the N-terminal portion 42.

Each source electrode 112 is further connected to the conductive layer 27 by a wire 73b. The conductive layer 27 is connected to the second sense source terminal portion 45b by a wire 74b. As a result, each source electrode 112 and the second sense source terminal portion 45b are electrically connected.

The gate electrode 123 of each second transistor 12 is connected to the conductive layer 26 by a wire 72b. The conductive layer 26 is connected to the second gate terminal portion 46b by a wire 75b. Thus, each gate electrode 123 is electrically connected to the second gate terminal portion 46b.

The sense drain terminal portion 47 is connected to the conductive layer 22 by a wire 91. As a result, the drain electrode 111 and the sense drain terminal portion 47 are electrically connected.

The first thermistor terminal portion 48a is connected to the conductive layer 29a by a wire 92a, and the second thermistor terminal portion 48b is connected to the conductive layer 29b by a wire 92b. Thus, the thermistor S is electrically connected to the first thermistor terminal portion 48a and the second thermistor terminal portion 48b.

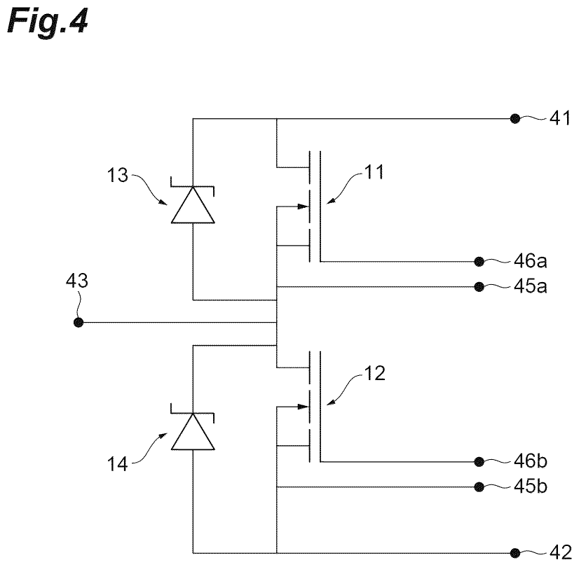

FIG. 4 is a diagram for explaining an electric circuit corresponding to the semiconductor device 1.

With the above wiring structure, as illustrated in FIG. 4, the first transistor 11 and the first diode 13 are connected in anti-parallel between the P-terminal portion 41 and the O-terminal portion 43. The second transistor 12 and the second diode 14 are connected in anti-parallel between the O-terminal portion 43 and the N-terminal portion 42. Further, the first transistor 11 and the second transistor 12 between the P-terminal portion 41 and the N-terminal portion 42 are connected in series. In such a configuration, the semiconductor device 1 functions as a power conversion circuit. In the power conversion circuit, the first transistor 11 is a transistor included in an upper arm, and the second transistor 12 is a transistor included in a lower arm.

FIG. 4 illustrates an electric circuit focusing on one set of the first transistor 11 and the second transistor 12. In the wiring structure illustrated in FIG. 1, the plurality of first transistors 11 are connected in parallel, the plurality of second transistors 12 are connected in parallel, the plurality of first diodes 13 are connected in parallel, and the plurality of second diodes 14 are connected in parallel. Accordingly, as illustrated in FIG. 4, the electric circuit realized by the semiconductor device 1 corresponds to a circuit in which a plurality of sets of the first transistor 11 to which the first diode 13 is connected in anti-parallel and the second transistor 12 to which the second diode 14 is connected in anti-parallel are connected in parallel.

In the semiconductor device 1, the plurality of first transistors 11, the plurality of second transistors 12, the plurality of first diodes 13, the plurality of second diodes 14, wiring structures thereof, and the like arranged inside the case 30 may be embedded with an insulating resin. In this case, since the insulating resin is also arranged between the conductive portion 51 and the conductive portion 52, insulation between the conductive portion 51 and the conductive portion 52 is secured. An example of the insulating resin is a silicone gel.

The semiconductor device 1 is manufactured as follows, for example.

The plurality of first transistors 11, the plurality of second transistors 12, the plurality of first diodes 13, and the plurality of second diodes 14 are mounted on the circuit board 20. The first transistors 11, the second transistors 12, the first diodes 13, and the second diodes 14 can be mounted on the circuit board 20 by, for example, die bonding. The case 30 in which the P-terminal portion 41, the metal plate 2, the metal plate 3, the first gate terminal portion 46a, the second gate terminal portion 46b, and the like are assembled is prepared. Since the metal plate 2 has the N-terminal portion 42 and the conductive portion 51 and the metal plate 3 has the O-terminal portion 43 and the conductive portion 52, the N-terminal portion 42, the conductive portion 51, the O-terminal portion 43, and the conductive portion 52 are also assembled to the case 30 prepared as described above. In a case where the material of the case 30 is resin, the case 30 can be prepared by, for example, insert molding. An order of a process of mounting the first transistors 11, the second transistors 12, and the like on the circuit board 20 and a process of preparing the case 30 is not limited.

Subsequently, the circuit board 20 on which the first transistors 11, the second transistors 12, and the like are mounted is attached to the case 30. Specifically, the circuit board 20 is attached to a lower opening of the case 30 such that the first transistors 11, the second transistors 12, and the like are positioned inside the case 30. As a result, the lower opening of the case 30 is closed by the circuit board 20. The circuit board 20 and the case 30 are bonded to each other by, for example, an adhesive.

Thereafter, necessary wiring in the semiconductor device 1 is performed to realize the wiring structure described with reference to FIGS. 1 and 3. The wiring can be performed by wire bonding using ultrasonic waves or the like. Thus, the semiconductor device 1 is obtained. In an aspect in which the plurality of first transistors 11, the plurality of second transistors 12, and the like on the circuit board 20 arranged inside the case 30 are embedded with the insulating resin, after the wiring is performed, the insulating resin may be injected into a space formed by the side wall portion 31, the side wall portion 32, the side wall portion 33, and the side wall portion 34 of the case 30 and the circuit board 20.

In the semiconductor device 1, the source electrode 112 of the first transistor 11 is electrically connected to the O-terminal portion 43 by the conductive portion 52. Accordingly, a current between the source electrode 112 and the O-terminal portion 43 flows through the conductive portion 52. The source electrode 122 of the second transistor 12 is electrically connected to the N-terminal portion 42 by the conductive portion 51. Accordingly, the current between the source electrode 122 and the N-terminal portion 42 flows through the conductive portion 51.

In this case, a direction of a change (increase or decrease) in the current flowing through the conductive portion 51 and the conductive portion 52 is opposite between the conductive portion 51 and the conductive portion 52. The conductive portion 51 and the conductive portion 52 have a plate shape and are arranged in parallel to each other. That is, the conductive portion 51 and the conductive portion 52 are arranged in a parallel flat plate state (hereinafter, such an arrangement state is referred to as “parallel plate arrangement”). Thus, for example, in a case where the current flows through the conductive portion 51 and the conductive portion 52 by switching control of each of the first transistor 11 and the second transistor 12, magnetic fluxes generated by the change in the current are mutually canceled. As a result, a low inductance of the semiconductor device 1 can be realized.

The parallel plate arrangement of the conductive portion 51 and the conductive portion 52 is performed in a state where thickness directions thereof face the Z direction. Accordingly, for example, even in the case of the thin semiconductor device 1, it is easy to realize the low inductance. The thin semiconductor device 1 is a semiconductor device having a short length in the Z direction. An example of the length in the Z direction in the thin semiconductor device 1 is 15 mm to 25 mm. Since the parallel plate arrangement of the conductive portion 51 and the conductive portion 52 is performed as described above, even in the thin semiconductor device 1, it is possible to secure a degree of freedom in designing the semiconductor device 1 while realizing the low inductance as described above.

In the semiconductor device 1, the drain electrode 111 of the first transistor 11 is bonded to the conductive layer 22, and the drain electrode 121 of the second transistor 12 is bonded to the conductive layer 23. Accordingly, in the semiconductor device 1, the current on the drain side of each of the first transistor 11 and the second transistor 12 flows through the conductive layer 22 and the conductive layer 23. The conductive layer 22 and the conductive layer 23 are arranged adjacent to each other. Accordingly, the magnetic fluxes generated by the change in the current on the drain side of the first transistor 11 and the second transistor 12 also cancel each other. As a result, an inductance on the drain side of each of the first transistor 11 and the second transistor 12 can be reduced.

As described above, in the semiconductor device 1, since the inductance can be reduced, a surge voltage can be suppressed even though a switching speeds of the first transistor 11 and the second transistor 12 are increased.

The conductive portion 51 and the conductive portion 52 are separated from the circuit board 20 and are parallel to the circuit board 20. Such an arrangement can be easily realized by fixing the conductive portion 51 and the conductive portion 52 to the case 30 as described in the first embodiment. In an aspect in which the conductive portion 51 and the conductive portion 52 are arranged as described above, the thin semiconductor device 1 can be easily realized.

In the first embodiment, the metal plate 2 in which the conductive portion 51 and the N-terminal portion 42 are integrated and the metal plate 3 in which the conductive portion 52 and the O-terminal portion 43 are integrated are adopted. In such an aspect, the conductive portion 51, the conductive portion 51, the N-terminal portion 42, and the O-terminal portion 43 can be easily fixed to the case 30 by fixing the metal plates 2 and 3 to the case 30.

### Second Embodiment

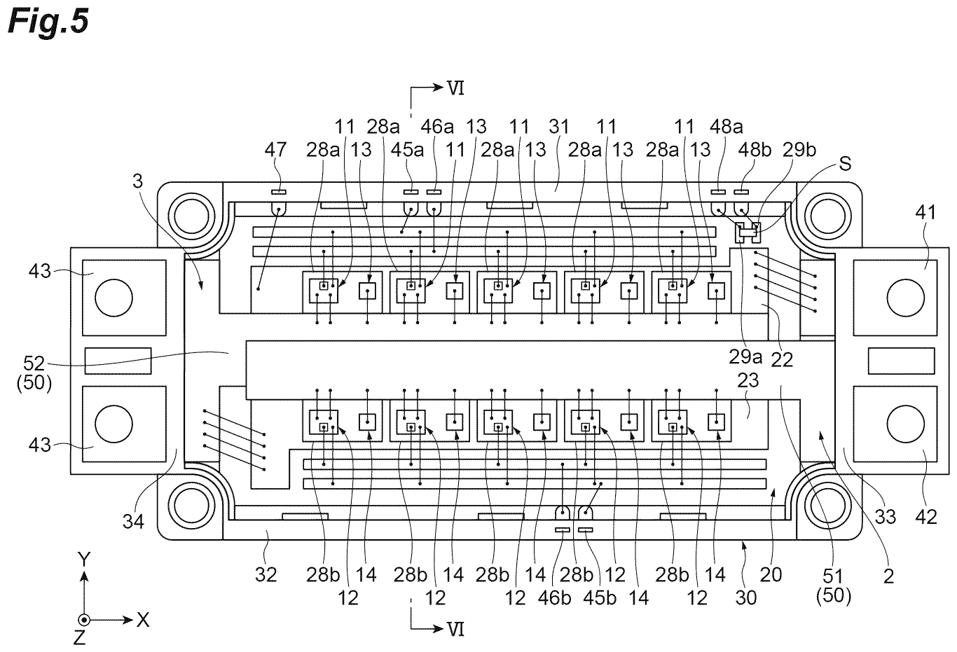

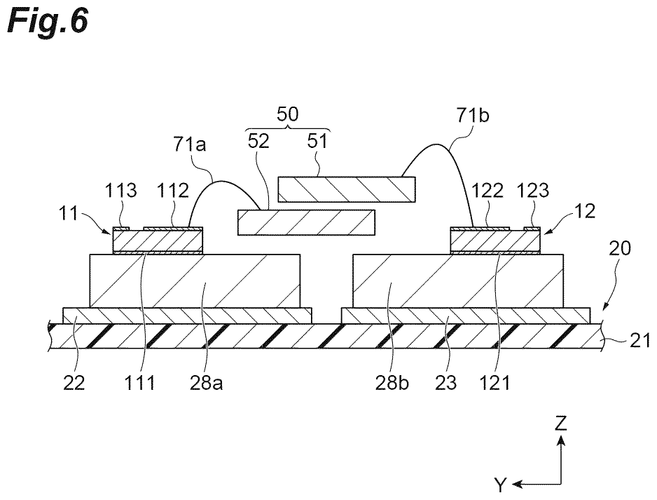

FIG. 5 is a plan view illustrating a semiconductor device according to a second embodiment. FIG. 6 is a diagram schematically illustrating a part of a sectional structure taken along line VI-VI in FIG. 5.

As illustrated in FIGS. 5 and 6, a semiconductor device 1A illustrated in FIG. 5 is mainly different from the semiconductor device 1 in further including a plurality of first heat dissipation members 28a and a plurality of second heat dissipation members 28b. The semiconductor device 1A will be described focusing on this difference.

The plurality of first heat dissipation members 28a are mounted on the conductive layer 22. The plurality of second heat dissipation members 28b are mounted on the conductive layer 23. The first heat dissipation member 28a and the second heat dissipation member 28b are made of a material having high thermal conductivity. The first heat dissipation member 28a and the second heat dissipation member 28b according to the second embodiment have conductivity. Examples of materials of the first heat dissipation member 28a and the second heat dissipation member 28b include copper and silver. The first heat dissipation member 28a and the second heat dissipation member 28b are, for example, heat spreaders having conductivity.

The first heat dissipation member 28a is bonded to the conductive layer 22 by a bonding material having conductivity. Examples of the bonding material having conductivity include solder and a sintered material. The first transistor 11 and the first diode 13 are mounted on the first heat dissipation member 28a. The drain electrode 111 of the first transistor 11 and the cathode electrode of the first diode 13 are bonded to the first heat dissipation member 28a by a bonding material having conductivity. Thus, the drain electrode 111 of the first transistor 11 and the cathode electrode of the first diode 13 are electrically connected to the first heat dissipation member 28a and the conductive layer 22.

The second heat dissipation member 28b is bonded to the conductive layer 23 by a bonding material having conductivity. The second transistor 12 and the second diode 14 are mounted on the second heat dissipation member 28b. The drain electrode 121 of the second transistor 12 and the cathode electrode of the second diode 14 are bonded to the second heat dissipation member 28b by a bonding material having conductivity. Thus, the drain electrode 121 of the second transistor 12 and the cathode electrode of the second diode 14 are electrically connected to the second heat dissipation member 28b and the conductive layer 23.

As described above, the drain electrode 111 of the first transistor 11 and the cathode electrode of the first diode 13 mounted on the first heat dissipation member 28a are electrically connected to the conductive layer 22. The drain electrode 121 of the second transistor 12 and the cathode electrode of the second diode 14 mounted on the second heat dissipation member 28b are electrically connected to the conductive layer 23. Further, the configuration of the semiconductor device 1A other than the semiconductor device 1 includes the first heat dissipation member 28a and the second heat dissipation member 28b is substantially the same as in the first embodiment. Accordingly, the semiconductor device 1A has the same or similar operations and effects as the semiconductor device 1.

Since the first transistor 11 and the second transistor 12 are arranged on the first heat dissipation member 28a and the second heat dissipation member 28b, heat generated in the first transistor 11 and the second transistor 12 can be efficiently dissipated.

Since the first transistor 11 and the second transistor 12 are arranged on the first heat dissipation member 28a and the second heat dissipation member 28b, the first transistor 11 and the second transistor 12 can be arranged in a state of being close to the wiring portion 50. Specifically, the first transistor 11 and the second transistor 12 can be arranged in a state of being close to the conductive portion 51 and the conductive portion 52. As a result, stress generated in necks of the wires 71a and 71b can be reduced. The same applies to the wire 76a and the wire 76b connecting the first diode 13 and the second diode 14, and the conductive portion 51 and the conductive portion 52.

### Third Embodiment

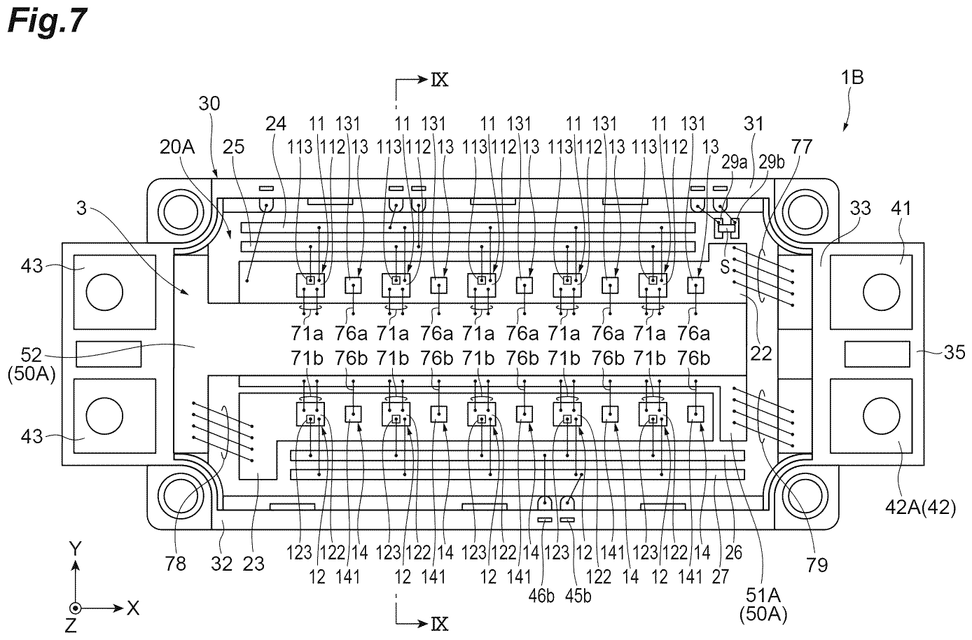

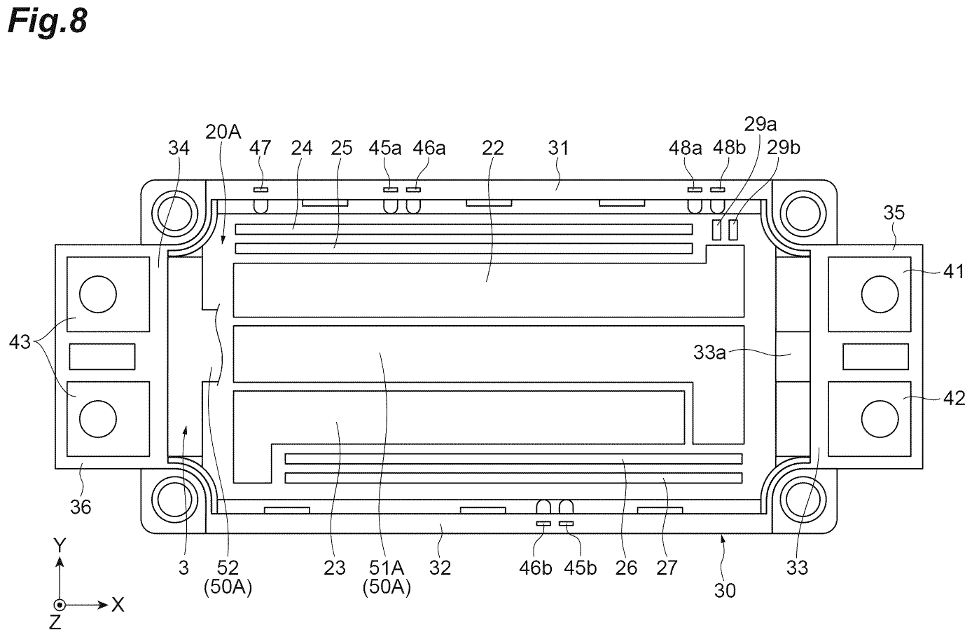

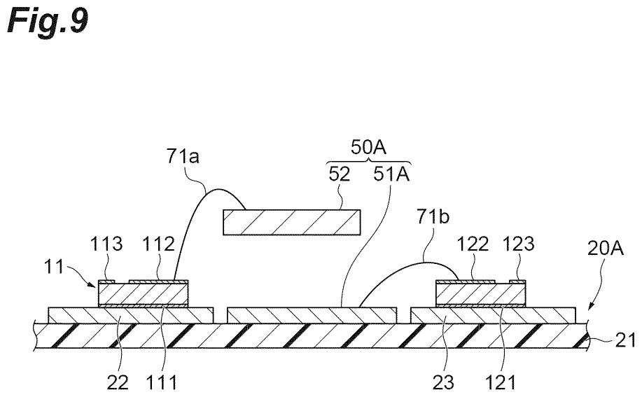

FIG. 7 is a plan view illustrating a semiconductor device according to a third embodiment. FIG. 8 is a diagram for explaining a circuit board included in a semiconductor device 1B illustrated in FIG. 7. In FIG. 8, in order to illustrate a circuit board 20A, illustration of a wiring structure using the first transistor 11, the second transistor 12, the first diode 13, the second diode 14, the wires 71a and 71b, and the like is omitted while a part of the metal plate 3 is cut out. FIG. 9 is a diagram schematically illustrating a part of a sectional structure taken along line IX-IX in FIG. 7.

The semiconductor device 1B is mainly different from the semiconductor device 1 in including the circuit board 20A instead of the circuit board 20 and including a wiring portion 50A instead of the wiring portion 50. The semiconductor device 1B will be described focusing on this difference.

As illustrated in FIG. 8, the circuit board 20A is different from the circuit board 20 in that a conductive layer (third conductive layer) 51A is formed between the conductive layer 22 and the conductive layer 23. The conductive layer 51A has a plate shape or a thin plate shape. The conductive layer 51A extends in the X direction.

In the semiconductor device 1B, the conductive portion 52, which is a partial region of the metal plate 3, is arranged on the conductive layer 51A. The conductive layer 51A and the conductive portion 52 are separated from each other in the Z direction. Thickness directions of the conductive layer 51A and the conductive portion 52 are oriented in the Z direction. The conductive layer 51A and the conductive portion 52 are arranged in parallel to each other. Accordingly, in the semiconductor device 1B, the conductive layer 51A and the conductive portion 52 constitute the wiring portion 50A.

The conductive layer 51A corresponds to the conductive portion 51 of the wiring portion 50. In the semiconductor device 1B, the conductive layer 51A and the N-terminal portion 42 are separated from each other. The N-terminal portion 42 in the semiconductor device 1B is referred to as an N-terminal portion 42A. The N-terminal portion 42A is, for example, a metal plate. An example of the N-terminal portion 42A is a bus bar.

A first end portion of the N-terminal portion 42 is exposed on the upper surface of the terminal block 35. A second end portion of the N-terminal portion 42A is exposed from the inner surface of the side wall portion 33. The second end portion of the N-terminal portion 42A is an end portion opposite to the first end portion of the N-terminal portion 42A. The second end portion of the N-terminal portion 42A is arranged on the stepped portion 33a. A part of the N-terminal portion 42A is embedded in the terminal block 35. Specifically, a portion between the first end portion and the second end portion of the N-terminal portion 42A is embedded in the terminal block 35.

As illustrated in FIG. 7, a portion of the second end portion of the N-terminal portion 42A exposed on the stepped portion 33a and the conductive layer 51A are connected by a wire 79. Thus, the conductive layer 51A and the N-terminal portion 42A are electrically connected.

The source electrode 122 of the second transistor 12 is connected to the conductive layer 51A by a wire 71b. The anode electrode 141 of the second diode 14 is connected to the conductive layer 51A by the wire 76b. As described above, since the conductive layer 51A and the N-terminal portion 42A are electrically connected, the source electrode 122 and the anode electrode 141 are electrically connected to the N-terminal portion 42A.

The wiring structure in the semiconductor device 1B is similar to the wiring structure in the semiconductor device 1 except that the source electrode 122 and the anode electrode 141 are electrically connected to the N-terminal portion 42A using the conductive layer 51A and the wire 79.

The semiconductor device 1B can be manufactured in a similar manner to the case of the semiconductor device 1 except that the circuit board 20A is prepared instead of the circuit board 20 and the case 30 incorporating the N-terminal portion 42A is prepared instead of the metal plate 2.

The semiconductor device 1B also includes the wiring portion 50A. The wiring portion 50A includes the conductive layer 51A and the conductive portion 52. An arrangement relationship between the conductive layer 51A and the conductive portion 52 is the same as an arrangement relationship between the conductive portion 51 and the conductive portion 51 except that the conductive layer 51A corresponding to the conductive portion 52 is arranged on the insulating substrate 21. Accordingly, the semiconductor device 1B has the same operations and effects as the operations and effects of the semiconductor device 1 including the wiring portion 50.

In the semiconductor device 1B, one of the two conductive portions included in the wiring portion 50A is formed as the conductive layer 51A on the insulating substrate 21. In this case, since the conductive layer 51A can be formed in a similar manner to the conductive layer 22, the conductive layer 23, and the like, the conductive layer 51A can be easily formed. As a result, it is easy to implement the wiring portion 50A on the semiconductor device 1B. Further, it is easy to secure insulation between the conductive layer 51A and the conductive portion 52.

### Fourth Embodiment

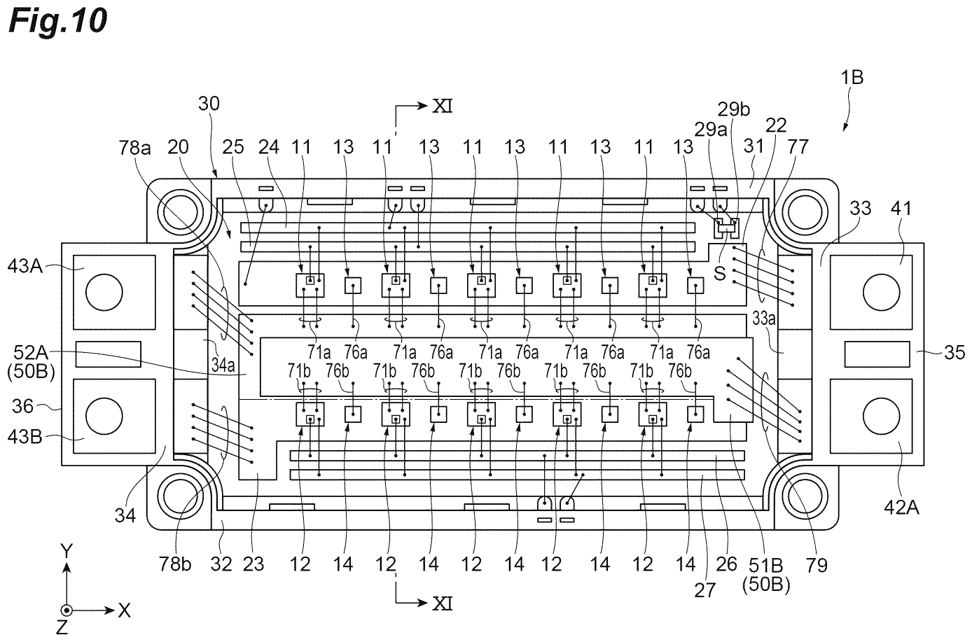

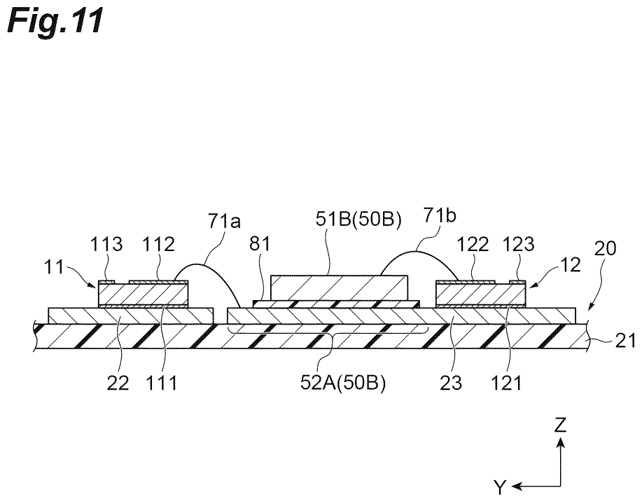

FIG. 10 is a plan view illustrating a semiconductor device according to a fourth embodiment. FIG. 11 is a diagram schematically illustrating a part of a sectional structure taken along line XI-XI in FIG. 10.

A semiconductor device 1C is different from the semiconductor device 1 mainly in that an N-terminal portion 42A is provided instead of the N-terminal portion 42, a first O-terminal portion 43A and a second O-terminal portion 43B are provided instead of the O-terminal portion 43, and a wiring portion 50B is provided instead of the wiring portion 50. The semiconductor device 1C will be described focusing on this difference.

The configuration, arrangement, and the like of the N-terminal portion 42A are in the same manner as in the case of the semiconductor device 1B. Accordingly, the description of the N-terminal portion 42A is omitted.

The first O-terminal portion 43A and the second O-terminal portion 43B are two separated terminal portions. The first O-terminal portion 43A and the second O-terminal portion 43B are attached to the terminal block 36. First end portions of the first O-terminal portion 43A and the second O-terminal portion 43B are exposed on the upper surface of the terminal block 36. Second end portions (end portions opposite to the first end portions) of the first O-terminal portion 43A and the second O-terminal portion 43B are exposed from the inner surface of the side wall portion 34. In the fourth embodiment, portions of the second end portions of the first O-terminal portion 43A and the second O-terminal portion 43B exposed in the case 30 are arranged on the stepped portion 34a. Parts (portions between the first end portion and the second end portion) of the first O-terminal portion 43A and the second O-terminal portion 43B are embedded in the terminal block 36.

The wiring portion 50B includes a conductive portion 51B and a conductive portion 52A.

The conductive portion 52A is a part of the conductive layer 23. Specifically, the conductive portion 52A is a region of the conductive layer 23 close to the conductive layer 22. In FIG. 10, a virtual boundary between a region of the conductive layer 23 corresponding to the conductive portion 52A and another region is indicated by a dashed dotted line. A width of the conductive layer 22 in the Y direction may be wider than in the case of the semiconductor device 1. Since the conductive portion 52A is a part of the conductive layer 23, the conductive portion has a plate shape or a layer shape. The conductive portion 52A is a separate member from the first O-terminal portion 43A and the second O-terminal portion 43B.

The conductive portion 51B is a plate-shaped member having conductivity. The conductive portion 51B is a metal plate. An example of the conductive portion 51B is a bus bar. The conductive portion 51B is arranged on the conductive portion 52A. An insulating paper (insulating member) 81 is provided between the conductive portion 51B and the conductive portion 52A.

A wiring structure of the semiconductor device 1C will be described.

The source electrode 112 of each first transistor 11 and the anode electrode 131 of each first diode 13 are connected, by the wire 71a, to the conductive portion 52A which is a part of the conductive layer 23 and the wire 76a. Thus, each source electrode 112 and each anode electrode 131 are electrically connected to the conductive portion 52A.

The first O-terminal portion 43A and the conductive layer 23 are connected by a wire 78a. The second O-terminal portion 43B and the conductive layer 23 are connected by a wire 78b. The second transistor 12 and the second diode 14 are mounted on the conductive layer 23. The method for mounting the second transistor 12 and the second diode 14 on the conductive layer 23 is in the same manner as in the case of the first embodiment. Accordingly, the conductive portion 52A which is a part of the conductive layer 23 is electrically connected to the source electrode 122 of the second transistor 12 and the cathode electrode (not illustrated) of the second diode 14, and is electrically connected to the first O-terminal portion 43A and the second O-terminal portion 43B.

The source electrode 122 of each second transistor 12 and the anode electrode 141 of each second diode 14 are connected to the conductive portion 51B by the wire 71b and the wire 76b. The conductive portion 51B is connected to the N-terminal portion 42A by the wire 79.

The wiring structure other than the above points is the same as the wiring structure of the first embodiment. Accordingly, the electric circuit realized by the semiconductor device 1C is in the same manner as in the case of the semiconductor device 1.

The semiconductor device 1C can be manufactured in a similar manner to the case of the semiconductor device 1 except that when the first transistor 11, the second transistor 12, and the like are mounted on the circuit board 20, the conductive portion 51B is mounted on the conductive layer 23, and the case 30 incorporating the N-terminal portion 42A, the first O-terminal portion 43A, and the second O-terminal portion 43B is prepared instead of the metal plate 2 and the metal plate 3. When the conductive portion 51B is mounted on the conductive layer 23, an insulating paper 81 is sandwiched between the conductive layer 23 and the conductive portion 51B. The insulating paper 81 may be any insulating paper usually used in the present technical field. An example of the insulating paper 81 is Nomex (registered trademark) paper. The bonding between the conductive layer 23 and the insulating paper 81 and the bonding between the insulating paper 81 and the conductive portion 51B can be performed by, for example, an adhesive. The process of mounting the conductive portion 51B on the conductive layer 23 may be performed before wiring is applied.

The semiconductor device 1C also includes the wiring portion 50B. The wiring portion 50B includes a plate-shaped conductive portion 51B and a plate-shaped conductive portion 52A arranged in parallel to each other along the Z direction. Accordingly, the semiconductor device 1B has the same operations and effects as the operations and effects of the semiconductor device 1 including the wiring portion 50.

The conductive portion 52A included in the wiring portion 50B is a part of the conductive layer 23. In the fourth embodiment, the conductive portion 51B is arranged on the conductive layer 23. The conductive portion 51B is a separate member from the N-terminal portion 42A. In such a configuration, the wiring portion 50B can be realized by mounting the conductive portion 51B on the conductive layer 23 in a state where the conductive layer 23 and the conductive portion 51B are insulated from each other. Thus, it is easy to implement the wiring portion 50B on the semiconductor device 1C. Since the conductive portion 52A is a part of the conductive layer 23, the configuration of the semiconductor device 1C is simple. Since the conductive portion 52A uses a part of the conductive layer 23 as the conductive portion 52, the manufacturing cost of the semiconductor device 1C can be reduced.

The insulating paper 81 is arranged between the conductive portion 51B and the conductive portion 52A. With the insulating paper 81, the uniformity of a distance between the conductive portion 51B and the conductive portion 52A can be secured along extending directions of the conductive portion 51B and the conductive portion 52A, and as a result, the parallel states of the conductive portion 51B and the conductive portion 52A can be maintained. The insulating paper 81 can reliably prevent a short circuit between the conductive portion 51B and the conductive portion 52A. Thus, the distance between the conductive portion 51B and the conductive portion 52A can be shortened. In this way, the insulating paper 81 makes it possible to secure the insulation of the conductive portion 51B and the conductive portion 52A while maintaining the parallel states of the conductive portion 51B and the conductive portion 52A along the extending directions, and thus further reducing the inductance.

In the semiconductor device 1C, the conductive layer 22 and the conductive layer 23 are also adjacent to each other in the Y direction. Thus, similarly to the case of the first embodiment, the magnetic fluxes generated by the change in the current on the drain side of each of the first transistor 11 and the second transistor 12 also cancel each other. As a result, an inductance on the drain side of each of the first transistor 11 and the second transistor 12 can be reduced.

### Modification 1

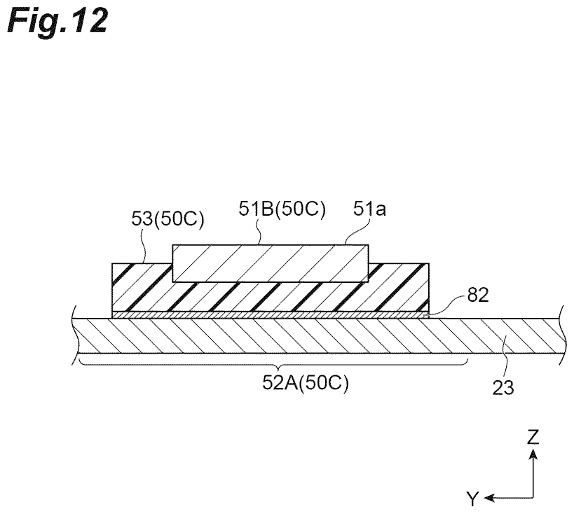

FIG. 12 is a diagram illustrating a modification of the wiring portion. A wiring portion 50C illustrated in FIG. 12 includes the conductive portion 51B, the conductive portion 52A, and an insulating resin portion 53.

Since the conductive portion 51B and the conductive portion 52A are in the same manner as in the case of the semiconductor device 1C described with reference to FIGS. 10 and 11, the description thereof will be omitted.

The insulating resin portion 53 is made of an insulating resin. Examples of the insulating resin include polyphenylene sulfide (PPS), polyether ether ketone (PEEK), and polycarbonate (PC).

In the wiring portion 50C, the conductive portion 51B is inserted into the insulating resin portion 53. Specifically, the conductive portion 51B is inserted into the insulating resin portion 53 such that a surface 51a of the conductive portion 51B is exposed. In Modification 1, the insulating resin portion 53 is fixed to the conductive portion 52A by using an insulating adhesive 82. Thus, the conductive portion 51B inserted into the insulating resin portion 53 is fixed to the conductive portion 52A which is a part of the conductive layer 23. In this case, the surface 51a of the conductive portion 51B is exposed from the insulating resin portion 53. Thus, the wires 71b and 76b and the like can be easily connected. The surface 51a is a surface of the conductive portion 51B opposite to the conductive layer 23.

The arrangement aspect of the conductive portion 51B and the conductive portion 52A according to Modification 1 is the same as the arrangement aspect of the conductive portion 51B and the conductive portion 52A illustrated in FIG. 11 except that the insulating resin portion 53 is arranged between the conductive portion 51B and the conductive portion 52A. Accordingly, instead of the arrangement aspect of the conductive portion 51B and the conductive portion 52A illustrated in FIG. 11, a semiconductor device adopting the arrangement aspect of Modification 1 also has the same operations and effects as the semiconductor device 1C. Since the insulating resin portion 53 is arranged between the conductive portion 51B and the conductive portion 52A, the insulation between the conductive portion 51B and the conductive portion 52A can be further secured.

### Modification 2

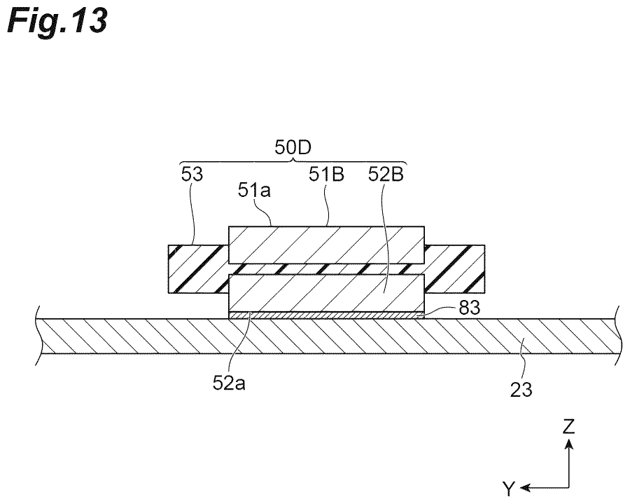

FIG. 13 is a diagram illustrating another modification of the wiring portion. A wiring portion 50D illustrated in FIG. 13 includes a conductive portion 51B, a conductive portion 52B, and an insulating resin portion 53.

The conductive portion 51B is in the same manner as in the case of the semiconductor device 1C described with reference to FIGS. 10 and 11. The insulating resin portion 53 is the same as the insulating resin portion 53 described in Modification 1. Accordingly, the description of the conductive portion 51B and the insulating resin portion 53 is omitted.

The conductive portion 52B is a separate member from the first O-terminal portion 43A, the second O-terminal portion 43B, and the conductive layer 23. Similarly to the conductive portion 51B, the conductive portion 52B is a plate-shaped member having conductivity. The conductive portion 52B extends in a direction orthogonal to the Y direction and the Z direction illustrated in FIG. 13. The conductive portion 52B is, for example, a metal plate. An example of the conductive portion 52B is a bus bar.

In the wiring portion 50D, the conductive portion 51B and the conductive portion 52B are inserted into the insulating resin portion 53. Specifically, the conductive portion 51B and the conductive portion 52B are inserted into the insulating resin portion 53 such that the surface 51a of the conductive portion 51B and a surface 52a of the conductive portion 52A are exposed from the insulating resin portion 53. In this aspect, the surface 52a of the conductive portion 52B is fixed to the conductive layer 23 by using a bonding material 83 having conductivity. Thus, the wiring portion 50D is fixed to the conductive layer 23. The surface 52a is a surface of the conductive portion 52B close to the conductive layer 23.

Since the bonding material 83 has conductivity, the conductive portion 52B and the conductive layer 23 are electrically connected. Accordingly, in Modification 2, the conductive portion 51B is arranged on the conductive portion 52B electrically connected to the conductive layer 23. The insulating resin portion 53 is sandwiched between the conductive portion 51B and the conductive portion 52B. Thus, the arrangement aspect of the conductive portion 52B and the conductive portion 51B according to Modification 2 is substantially similar to the case of Modification 1. Accordingly, similarly to the case of Modification 1, the semiconductor device adopting the arrangement aspect of Modification 2 also has the same operations and effects as the semiconductor device 1C.

Although various embodiments and modifications according to the present disclosure have been described above, the present disclosure is not limited to the illustrated embodiments and modifications.

In the first embodiment, the conductive portion 51 and the N-terminal portion 42 may also be separate members, and the conductive portion 52 and the O-terminal portion 43 may also be separate members. In this case, one end portion of the conductive portion 51 and one end portion of the conductive portion 52 may be connected to the N-terminal portion 42 and the O-terminal portion 43 by, for example, a bonding material having conductivity. For the sake of convenience in the following description, the conductive portion 51 that is the separate member from the N-terminal portion 42 and the conductive portion 52 that is the separate member from the O-terminal portion 43 will be referred to as the conductive portion 51B and the conductive portion 52B as in the case of FIG. 13.

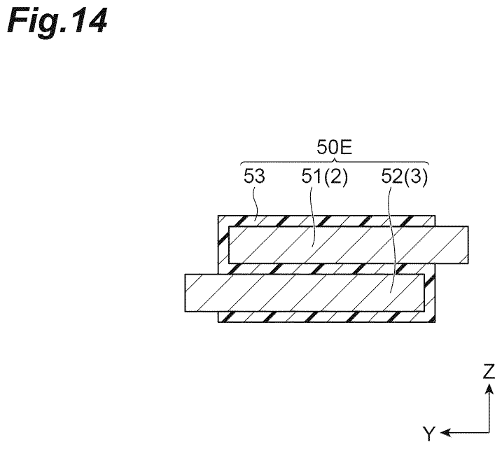

In the first embodiment, the wiring portion 50E illustrated in FIG. 14 may be adopted instead of the wiring portion 50. The wiring portion 50E includes the conductive portion 51 which is a part of the metal plate 2, the conductive portion 52 which is a part of the metal plate 3, and the insulating resin portion 53. The conductive portion 51 and the conductive portion 52 are inserted into the insulating resin portion 53 such that a part thereof is exposed from the insulating resin portion 53. In the wiring portion 50E, a part of the insulating resin portion 53 is sandwiched between the conductive portion 51 and the conductive portion 52. Accordingly, it is easy to secure the insulation between the conductive portion 51 and the conductive portion 52. Since parts of the conductive portion 51 and the conductive portion 52 are exposed from the insulating resin portion 53, it is easy to connect the wires 71a and 71b and the like to the conductive portion 51 and the conductive portion 52. FIG. 14 illustrates a case where the vicinity of the edge portion of each of the conductive portion 51 and the conductive portion 52 is exposed from the insulating resin portion 53. However, a region for connecting the wires 71a and 71b and the like to the conductive portion 51 and the conductive portion 52 is secured.

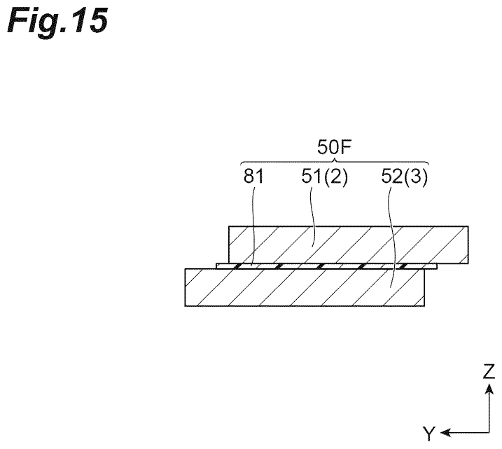

In the first embodiment, a wiring portion 50F illustrated in FIG. 15 may be adopted instead of the wiring portion 50. The wiring portion 50F includes the conductive portion 51 which is a part of the metal plate 2, the conductive portion 52 which is a part of the metal plate 3, and the insulating paper 81. The insulating paper 81 is sandwiched between the conductive portion 51 and the conductive portion 52. In the wiring portion 50F, since the insulating paper 81 is arranged between the conductive portion 51 and the conductive portion 52, a distance between the conductive portion 51 and the conductive portion 52 can be defined by a thickness of the insulating paper 81. Thus, the uniformity of the distance between the conductive portion 51 and the conductive portion 52 can be secured along the extending directions of the conductive portion 51 and the conductive portion 52, and as a result, the parallel states of the conductive portion 51 and the conductive portion 52 can be maintained. Further, the insulation between the conductive portion 51 and the conductive portion 52 can be secured by the insulating paper 81.

The conductive portion 51 and the conductive portion 52 illustrated in FIGS. 14 and 15 are a part of the metal plate 2 including the N-terminal portion 42 and the metal plate 3 including the O-terminal portion 43. However, in each of the wiring portion 50E and the wiring portion 50F, the conductive portion 51B that is the separate member from the N-terminal portion 42 may be adopted as the conductive portion 51, and the conductive portion 52B that is the separate member from the O-terminal portion 43 may be adopted as the conductive portion 52. In this case, an end portion of the conductive portion 51B close to the N-terminal portion 42 may be connected to the N-terminal portion 42 by, for example, a bonding material having conductivity, and an end portion of the conductive portion 52B close to the O-terminal portion 43 may be connected to the O-terminal portion 43 by, for example, a bonding material having conductivity. Alternatively, the wiring portion 50E may be fitted into the case 30 in the manufacturing procedure of the semiconductor device. In this case, the conductive portion 51B and the conductive portion 52B can be connected to the N-terminal portion 42 and the O-terminal portion 43 by a wiring member such as a wire.

The conductive portion 51 according to the first embodiment and the second embodiment may be fixed to, for example, the side wall portion 31 or the side wall portion 32 of the case 30. The conductive portion 51B according to the fourth embodiment may be fixed to, for example, the side wall portion 31 or the side wall portion 32 of the case 30. The conductive portion 52 according to the first to third embodiments may be fixed to, for example, the side wall portion 31 or the side wall portion 32 of the case 30. In a case where the conductive portion 51, the conductive portion 51B, the conductive portion 52, and the like are fixed to the side wall portion 31 or the side wall portion 32, the conductive portions can be fixed in a beam shape. In this case, for example, in a case where wire bonding is performed by using an ultrasonic wave, the ultrasonic wave is easily transmitted to the conductive portion 51, the conductive portion 51B, the conductive portion 52, and the like.

The end portion of the O-terminal portion 43 exposed on the upper surface of the terminal block 36 does not need to be branched into two. The semiconductor device 1C according to the fourth embodiment may include one O-terminal portion instead of the first O-terminal portion 43A and the second O-terminal portion 43B.

In the third embodiment, the conductive portion 52B described in Modification 2 may be arranged on the conductive layer 51A with the insulating paper 81 interposed therebetween. As described in Modification 2, the conductive portion 52B is a separate member from the O-terminal portion. Modification 1 may be applied to the third embodiment. That is, in the third embodiment, the conductive portion 52B inserted into the insulating resin portion 53 may be arranged on the conductive layer 51A.

That is, in a case where one of the first plate-shaped conductive portion and the second plate-shaped conductive portion is referred to as an i-th plate-shaped conductive portion (i is 1 or 2), the present disclosure can also be applied to an aspect in which the i-th plate-shaped conductive portion is arranged on the circuit board. Further, in a case where the plate-shaped conductive portion of the first plate-shaped conductive portion and the second plate-shaped conductive portion other than the i-th plate-shaped conductive portion is referred to as a k-th plate-shaped conductive portion (k is other than i of 1 and 2), the k-th plate-shaped conductive portion may be arranged on the i-th conductive portion with an insulating paper interposed therebetween. Alternatively, the wiring portion may have the insulating resin portion. In a case where the plate-shaped conductive portion of the first plate-shaped conductive portion and the second plate-shaped conductive portion other than the i-th plate-shaped conductive portion is referred to as the k-th plate-shaped conductive portion as described above, the k-th plate-shaped conductive portion may be inserted into the insulating resin portion, a part of the k-th plate-shaped conductive portion may be exposed from the insulating resin portion, and the k-th plate-shaped conductive portion may be arranged on the i-th plate-shaped conductive portion in a state where the insulating resin portion is sandwiched between the k-th plate-shaped conductive portion and the i-th plate-shaped conductive portion.

In the fourth embodiment, the conductive portion (first plate-shaped conductive portion) 51B and the conductive portion (second plate-shaped conductive portion) 52A may be separated from each other without the insulating paper 81.

The wiring member for realizing an electrical connection relationship between elements in the semiconductor device is not limited to the wire. Another example of the wiring member is a ribbon.

The number of first transistors included in the semiconductor device may be one or two or more. The number of second transistors included in the semiconductor device may be one or two or more.

The first transistor and the second transistor are not limited to MOSFETs. The first transistor and the second transistor may be, for example, an insulated gate bipolar transistor (IGBT).

The various embodiments and modifications described above may be appropriately combined without departing from the gist of the present disclosure.

### REFERENCE SIGNS LIST

1, 1A, 1B, 1C semiconductor device
2 metal plate
3 metal plate
11 first transistor
12 second transistor
13 first diode
14 second diode
20, 20A circuit board
21 insulating substrate
21a edge portion
21b edge portion
22 conductive layer (first conductive layer)
23 conductive layer (second conductive layer)
24 conductive layer
25 conductive layer
26 conductive layer
27 conductive layer
28a first heat dissipation member
28b second heat dissipation member
29a conductive layer
29b conductive layer
30 case
31 side wall portion
31a stepped portion
32 side wall portion
32a stepped portion
33 side wall portion
33a stepped portion
34 side wall portion
34a stepped portion
35 terminal block
36 terminal block
41 P-terminal portion
42, 42A N-terminal portion
43 O-terminal portion
43A first O-terminal portion
43B second O-terminal portion
45a first sense source terminal portion
45b second sense source terminal portion
46a first gate terminal portion
46b second gate terminal portion
47 sense drain terminal portion
48a first thermistor terminal portion
48b second thermistor terminal portion
50, 50A, 50B, 50C, 50D, 50E, 50F wiring portion
51, 51B conductive portion (first plate-shaped conductive portion)
51A conductive layer (first plate-shaped conductive portion)
51a surface
52, 52A, 52B conductive portion (second plate-shaped conductive portion)
52a surface
53 insulating resin portion
71a wire (wiring member)
71b wire (wiring member)
72a wire
72b wire
73a wire
73b wire
74b wire
75a wire
75b wire
76a wire
76b wire
77 wire (wiring member)
74a wire
78 wire (wiring member)
78a wire (wiring member)
78b wire (wiring member)
79 wire (wiring member)
81 insulating paper
82 adhesive
83 bonding material
91 wire
92a wire
92b wire
111 drain electrode (first electrode)
112 source electrode (second electrode)
113 gate electrode
121 drain electrode (first electrode)
122 source electrode (second electrode)
123 gate electrode
131 anode electrode
141 anode electrode
S thermistor

1. A semiconductor device comprising:
a circuit board including a first conductive layer electrically connected to a P-terminal portion and a second conductive layer electrically connected to an O-terminal portion;
a first transistor arranged on the first conductive layer, the first transistor including a first electrode electrically connected to the first conductive layer and a second electrode;
a second transistor arranged on the second conductive layer, the second transistor including a third electrode electrically connected to the second conductive layer and a fourth electrode; and
a wiring portion including a first plate-shaped conductive portion electrically connected to an N-terminal portion and a second plate-shaped conductive portion electrically connected to the O-terminal portion, wherein
the second electrode is electrically connected to the second plate-shaped conductive portion,
the fourth electrode is electrically connected to the first plate-shaped conductive portion,
thickness directions of the first plate-shaped conductive portion and the second plate-shaped conductive portion are along a thickness direction of the circuit board, and
the first plate-shaped conductive portion and the second plate-shaped conductive portion are arranged to be separated from each other in the thickness direction and in parallel to each other.

2. The semiconductor device according to claim 1, wherein
the first plate-shaped conductive portion and the second plate-shaped conductive portion are separated from the circuit board and are parallel to the circuit board.

3. The semiconductor device according to claim 2, further comprising a case configured to accommodate the first transistor and the second transistor arranged on the circuit board, wherein
the first plate-shaped conductive portion and the second plate-shaped conductive portion are fixed to the case.

4. The semiconductor device according to claim 3, further comprising:
the P-terminal portion;
the N-terminal portion; and
the O-terminal portion, wherein
the P-terminal portion, the N-terminal portion, and the O-terminal portion are fixed to the case,
the first plate-shaped conductive portion is directly connected to the N-terminal portion,
the second plate-shaped conductive portion is directly connected to the O-terminal portion,
the first conductive layer is connected to the P-terminal portion by a wiring member, and
the second conductive layer is connected to the O-terminal portion by a wiring member.

5. The semiconductor device according to claim 3, wherein
the wiring portion includes an insulating resin portion configured to insulate the first plate-shaped conductive portion and the second plate-shaped conductive portion, and
the first plate-shaped conductive portion and the second plate-shaped conductive portion are inserted into the insulating resin portion.

6. The semiconductor device according to claim 3, wherein
the wiring portion includes an insulating paper configured to insulate the first plate-shaped conductive portion and the second plate-shaped conductive portion, and
the insulating paper is positioned between the first plate-shaped conductive portion and the second plate-shaped conductive portion.

7. The semiconductor device according to claim 2, further comprising:
a first heat dissipation member arranged between the first transistor and the first conductive layer; and
a second heat dissipation member arranged between the second transistor and the second conductive layer.

8. The semiconductor device according to claim 1, wherein
in a case where one of the first plate-shaped conductive portion and the second plate-shaped conductive portion is referred to as an i-th plate-shaped conductive portion (i is 1 or 2), the i-th plate-shaped conductive portion is arranged on the circuit board.

9. The semiconductor device according to claim 8, wherein
in a case where a plate-shaped conductive portion other than the i-th plate-shaped conductive portion, of the first plate-shaped conductive portion and the second plate-shaped conductive portion, is referred to as a k-th plate-shaped conductive portion (k is other than i of 1 and 2), the k-th plate-shaped conductive portion is arranged on the i-th plate-shaped conductive portion with an insulating paper interposed therebetween.

10. The semiconductor device according to claim 8, wherein
the wiring portion includes an insulating resin portion, and
in a case where a plate-shaped conductive portion other than the i-th plate-shaped conductive portion, of the first plate-shaped conductive portion and the second plate-shaped conductive portion, is referred to as a k-th plate-shaped conductive portion (k is other than i of 1 and 2),
the k-th plate-shaped conductive portion is inserted into the insulating resin portion,
a part of the k-th plate-shaped conductive portion is exposed from the insulating resin portion, and
the k-th plate-shaped conductive portion is arranged on the i-th plate-shaped conductive portion in a state where the insulating resin portion is sandwiched between the k-th plate-shaped conductive portion and the i-th plate-shaped conductive portion.

11. The semiconductor device according to claim 8, wherein
the i-th plate-shaped conductive portion is the second plate-shaped conductive portion, and
the second plate-shaped conductive portion is a part of the second conductive layer.

12. The semiconductor device according to claim 8, wherein
the i-th plate-shaped conductive portion is the second plate-shaped conductive portion,
the second plate-shaped conductive portion is a part of the second conductive layer,
the wiring portion includes an insulating resin portion,
the first plate-shaped conductive portion and the second plate-shaped conductive portion are inserted into the insulating resin portion,
a part of each of the first plate-shaped conductive portion and the second plate-shaped conductive portion is exposed from the insulating resin portion, and
the second plate-shaped conductive portion is fixed to the second conductive layer in a state where a portion of the second plate-shaped conductive portion exposed from the insulating resin portion is electrically connected to the second conductive layer.

13. The semiconductor device according to claim 11, further comprising:
the P-terminal portion;
the N-terminal portion; and
the O-terminal portion, wherein
the first conductive layer is connected to the P-terminal portion by a wiring member,
the second conductive layer is connected to the O-terminal portion by a wiring member, and
the first plate-shaped conductive portion is connected to the N-terminal portion by a wiring member.

14. The semiconductor device according to claim 1, wherein
the circuit board includes a third conductive layer arranged between the first conductive layer and the second conductive layer, and
the first plate-shaped conductive portion is the third conductive layer.

15. The semiconductor device according to claim 14, further comprising:
the P-terminal portion;
the N-terminal portion; and
the O-terminal portion, wherein
the first conductive layer is connected to the P-terminal portion by a wiring member,
the second conductive layer is connected to the O-terminal portion by a wiring member,
the third conductive layer is connected to the N-terminal portion by a wiring member, and
the second plate-shaped conductive portion is connected to the O-terminal portion directly or by a wiring member.

16. The semiconductor device according to claim 4, wherein
the wiring portion includes an insulating resin portion configured to insulate the first plate-shaped conductive portion and the second plate-shaped conductive portion, and
the first plate-shaped conductive portion and the second plate-shaped conductive portion are inserted into the insulating resin portion.

17. The semiconductor device according to claim 4, wherein
the wiring portion includes an insulating paper configured to insulate the first plate-shaped conductive portion and the second plate-shaped conductive portion, and
the insulating paper is positioned between the first plate-shaped conductive portion and the second plate-shaped conductive portion.

18. The semiconductor device according to claim 12, further comprising:
the P-terminal portion;
the N-terminal portion; and
the O-terminal portion, wherein
the first conductive layer is connected to the P-terminal portion by a wiring member,
the second conductive layer is connected to the O-terminal portion by a wiring member, and
the first plate-shaped conductive portion is connected to the N-terminal portion by a wiring member.

19. The semiconductor device according to claim 1, further comprising:
a case configured to accommodate the first transistor and the second transistor arranged on the circuit board;
the P-terminal portion;
the N-terminal portion; and
the O-terminal portion, wherein
the case has a first side wall portion, a second side wall portion, a third side wall portion, a fourth side wall portion,
the first side wall portion and the second side wall portion face each other in a first direction which is orthogonal to the thickness direction of the circuit board,
the third side wall portion and the fourth side wall portion face each other in a second direction which is orthogonal to the thickness direction of the circuit board and the first direction,
the P-terminal portion and the N-terminal portion are fixed to the third side wall,
the O-terminal portion is fixed to the fourth side wall,
the first plate-shaped conductive portion and the second plate-shaped conductive portion extend in along the second direction, respectively, and
the first plate-shaped conductive portion and the second plate-shaped conductive portion at least partially overlap as viewed from the thickness direction of the circuit board.

20. The semiconductor device according to claim 1, further comprising:
a plurality of the first transistors; and
a plurality of the second transistors.
